(19) United States
(12) Patent Application Publication
(10) Pub. No.: US 2012/0012961 A1
(43) Pub. Date: Jan. 19, 2012

(54) SOLID-STATE IMAGING DEVICE AND METHOD OF MANUFACTURING OF SAME

(76) Inventors: Masao KATAOKA, Osaka (JP); Hiroshi Sakoh, Kyoto (JP)

(21) Appl. No.: 13/181,137

(22) Filed: Jul. 12, 2011

(30) Foreign Application Priority Data
Jul. 13, 2010 (JP) 2010-158809

(51) Int. Cl. H01L 27/146; H01L 31/18

(52) U.S. Cl. 257/432; 438/70; 257/E27.134

(57) ABSTRACT

A solid-state imaging device (101) includes an imaging area (1), an optical black area (2) provided at a periphery of the imaging area (1), and a light-absorption unit (21) provided above the optical black area (2). In the imaging area (1), a plurality of photoreceptors are arranged in a two-dimensional pattern, and in the optical black area (2), a plurality of photoreceptors are covered by a light-blocking film (15a). The light-absorption unit (21) includes a first filter (20b) and a second filter (20c) in an alternating arrangement, the first filter (20b) allowing visible light of a first type to pass through, and the second filter (20c) absorbing visible light of the first type that passes through the first filter (20b) and is reflected off the light-blocking film (15a).

### TECHNICAL FIELD

The present invention relates to a solid-state imaging device and a method of manufacturing of the same, and in particular to technology for achieving excellent image quality by improving the structure of an optical black area located around a pixel area and a peripheral area around the optical black area, and by reducing stray light entering into the pixel area.

### BACKGROUND ART

In recent years, solid-state imaging devices such as CCD image sensors or CMOS image sensors have been used in a variety of image input devices such as digital still cameras and fax machines.

A solid-state imaging device has an imaging area in which a plurality of photoreceptors (pixels) are arranged in a matrix. The photoreceptors generate signal charges in accordance with the amount of incident light, and the generated signal charges are output to an external unit as image signals.

FIG. 9 is a simplified plan view showing a structure of a conventional solid-state imaging device.

As shown in FIG. 9, the planar structure of a solid-state imaging device 900 can be widely divided into an imaging area 901, an optical black area 902 (hereinafter referred to as “OB area”) that surrounds the imaging area 901, and a peripheral area 903 that surrounds the OB area 902.

In the imaging area 901 and the OB area 902, photoreceptors such as photodiodes are arranged in a matrix. Unlike the photoreceptors in the imaging area 901, the photoreceptors in the OB area 902 are covered by a light-blocking film.

The peripheral area 903 includes peripheral circuitry for receiving the image signals from the photoreceptors in the imaging area 901 and the OB area 902, a plurality of bonding pads 904 used to connect the solid-state imaging device 900 to an external device, a plurality of metal wiring lines connecting the peripheral circuitry and the photoreceptors with the bonding pads 904, etc.

In order to adjust the brightness level of the image signals when processing the image signals read by the photoreceptors in the imaging area 901, dummy pixels having the same photoreceptive element structure as the imaging area 901, i.e. the actual area for taking an image of a object, are provided in the OB area 902. These dummy pixels are shielded from light by the light-blocking film, which is made of metal, thus forming a light-shielded pixel region. The output signal of this light-shielded pixel region is used as a black reference signal.

It is preferable that the black reference signal be detected with the pixels in the OB area 902 having, insofar as possible, the same characteristics as the pixels actually used for imaging. Therefore, the OB area 902 is normally provided beside the imaging area 901, as shown in FIG. 9. For example, a plurality of pixel rows along the imaging area 901, or a plurality of pixel blocks scattered around the imaging area 901, are provided to acquire an accurate black reference that adjusts for characteristic variance in pixels.

When acquiring a color image, light entering the imaging area 901 needs to be separated into color components for entry into the photoreceptors. To separate the light, color filters are used. One known method for more efficiently focusing light that enters the imaging area 901 on the photoreceptors is to further provide a microlens on the color filter.

The light that enters the photoreceptors of the imaging area 901 also enters the OB area 902 and the peripheral area 903. If light shielding is insufficient, the dummy pixels in the OB area 902 receive the incident light, yielding an incorrect signal as the black reference signal.

Furthermore, even if light shielding is sufficient, strong light is reflected off the surface of the light-blocking film in the OB area 902 and off the surface, such as the metal wiring, of the peripheral area 903. If the reflected light satisfies certain conditions, the light reflects off the bottom of the color filter, off the bottom of the microlens, etc. producing stray light in the imaging area.

Upon reaching the photoreceptors in the imaging area 901, such stray light produces undesired effects such as flares or ghosts. Technology to reduce the occurrence of such flares or ghosts has been proposed.

It has been proposed in Patent Literature 1, for example, to form the light-blocking film for the OB area from a metal such as aluminum, and to provide a blue color filter on the metal light-blocking film in order to restrict stray light having a long wavelength, which enters more easily.

Similarly, in Patent Literature 1, it is proposed to prevent unwanted light from entering or being reflected by providing dummy pixels above the metal light-blocking film in the OB area and further providing a blue color filter thereabove.

### Citation List

### [Patent Literature]

[Patent Literature 1]

Japanese Patent Application Publication No. 2007-42933

### SUMMARY OF INVENTION

### Technical Problem

The problem with the above-described structure in Patent Literature 1, however, is that when strong light enters near the OB area, although reflected light of a long wavelength is absorbed by the blue filter above the metal light-blocking film, reflected light of a short wavelength passes through, becoming stray light within the imaging device. This stray light then enters the imaging area 901 and the OB area 902 yielding an incorrect signal and causing degradation of image quality.

### Solution to Problem

In order to solve the above problem, the solid-state imaging device according to the present invention comprises: a substrate having an imaging area and an optical black area provided at a periphery of the imaging area, a plurality of first photoreceptors being arranged on the substrate in a two-dimensional pattern in the imaging area, and a plurality of second photoreceptors being arranged on the substrate and covered by a light-blocking film located in the optical black area; and a light-absorption unit provided above the optical black area, wherein the light-absorption unit includes a first filter and a second filter in an alternating arrangement, the first filter allowing visible light of a first type to pass through, and the second filter absorbing visible light of the first type that passes through the first filter and is reflected off the light-blocking film.

A method of manufacturing according to the present invention is for a solid-state imaging device with a substrate having an imaging area and an optical black area provided at a periphery of the imaging area, a plurality of first photoreceptors being arranged on the substrate in a two-dimensional pattern in the imaging area, and a plurality of second photoreceptors being arranged on the substrate and covered by a light-blocking film located in the optical black area, the method comprising: a formation step of forming a first filter and a second filter in an alternating arrangement above the optical black area, the first filter allowing visible light of a first type to pass through, and the second filter absorbing visible light of the first type that passes through the first filter and is reflected off the light-blocking film.

### Advantageous Effects of Invention

In the above solid-state imaging device, visible light of the first type that passes through the first filter and is reflected off the light-blocking film is absorbed by the second filter, which is arranged alternately with the first filter. This structure moderates a reduction in image quality due to stray light entering the imaging area.

The second filter may allow visible light of a second type to pass through, and the first filter may absorb visible light of the second type that passes through the second filter and is reflected off the light-blocking film. With this structure, visible light of the second type that passes through the second filter and is reflected off the light-blocking film is absorbed by the first filter, which is arranged alternately with the second filter. Since reflected visible light of the second type is thus absorbed, the occurrence of stray light in the solid-state imaging device is moderated, preventing a reduction in image quality.

The solid-state imaging device may further comprise a peripheral area provided at a periphery of the optical black area, the peripheral area including peripheral circuitry and a bonding pad, and the light-absorption unit may be formed above the peripheral area. With this structure, the occurrence of stray light in the peripheral area provided at the periphery of the optical black area is moderated, preventing a reduction in image quality.

The solid-state imaging device may further comprise a peripheral area provided at a periphery of the optical black area, the peripheral area including peripheral circuitry and a bonding pad, and a light-absorption layer provided above the peripheral area and including at least two types of filters having mutually different light-separation characteristics and provided layered on each other. With this structure, the capability to block light in the peripheral area provided at the periphery of the optical black area is improved while moderating the occurrence of stray light, thus preventing a reduction in image quality.

The light-absorption layer may include at least the first filter and the second filter. With this structure, the light-absorption layer and the light-absorption unit use the same filters, which reduces the number of manufacturing processes and the cost of material.

A plurality of different types of color filters may be provided in the imaging area in correspondence with the first photoreceptors in the imaging area, and the first filter and the second filter may each be of the same material as a respective one of the different types of color filters. This structure reduces the number of manufacturing processes and the cost of material.

At least one of the first filter and the second filter may be formed only from organic pigment and non-metallic material. This structure simplifies the etching process and allows for inexpensive manufacturing.

The solid-state imaging device may further comprise a light-absorption layer provided above the optical black area and including at least two types of filters having mutually different light-separation characteristics and provided layered on each other, and the light-absorption unit may be provided closer to the imaging area than the light-absorption layer is. With this structure, a difference in level in a foundation when forming the color filters and in subsequent processes is mitigated stepwise in the imaging area and the optical black area, thus reducing unevenness due to a large difference in level.

In the above method of manufacturing a solid-state imaging device, the first filter and the second filter are formed in an alternating arrangement. With this method, visible light of the first type that passes through the first filter and is reflected off the light-blocking film is absorbed by the second filter, which is arranged alternately with the first filter. This method allows for manufacturing of a solid-state imaging device that moderates a reduction in image quality due to stray light entering the imaging area.

The first filter and the second filter may be formed in a checkered pattern. This method effectively reduces stray light.

The solid-state imaging device may further include a peripheral area provided at a periphery of the optical black area, the peripheral area including peripheral circuitry and a bonding pad, and during the formation step, the first filter and the second filter may also be formed in the alternating arrangement in the peripheral area. With this method, the occurrence of stray light in the peripheral area provided at the periphery of the optical black area is moderated, preventing a reduction in image quality.

The solid-state imaging device may further include a peripheral area provided at a periphery of the optical black area, the peripheral area including peripheral circuitry and a bonding pad, and the method may further comprise, after forming the first filters and the second filters, the step of layering, in the peripheral area, at least two types of filters having mutually different light-separation characteristics. With this method, the capability to block light in the peripheral area provided at the periphery of the optical black area is improved while moderating the occurrence of stray light, thus preventing a reduction in image quality.

The first filter and the second filter may be formed from the same material as a plurality of color filters provided in the imaging area in correspondence with the photoreceptors in the imaging area. This method reduces the number of manufacturing processes and the cost of material.

The step of forming the first filter and the second filter may include forming a plurality of color filters in the imaging area in correspondence with the photoreceptors in the imaging area. This method reduces the number of manufacturing processes.

### BRIEF DESCRIPTION OF DRAWINGS

FIG. 1 is a plan view showing the imaging area, the OB area, and the peripheral area of the solid-state imaging device according to the Embodiments of the present invention.

FIG. 2 is a cross-section diagram showing the solid-state imaging device according to Embodiment 1.

FIG. 3 is a plan view showing the solid-state imaging device according to Embodiment 1.

FIG. 4 is a conceptual diagram of separation characteristics of primary color filters and the degree of reflection of an aluminum film.

FIGS. 5A, 5B, and 5C are conceptual diagrams of reflection characteristics of the OB area in the solid-state imaging device according to Embodiment 1.

FIG. 6 is a cross-section diagram showing the solid-state imaging device according to Embodiment 2.

FIG. 7 is a plan view showing the solid-state imaging device according to Embodiment 2.

FIGS. 8A, 8B, 8C, and 8D are plan views showing a light-absorption layer according to a Modification.

FIG. 9 is a plan view showing a conventional solid-state imaging device.

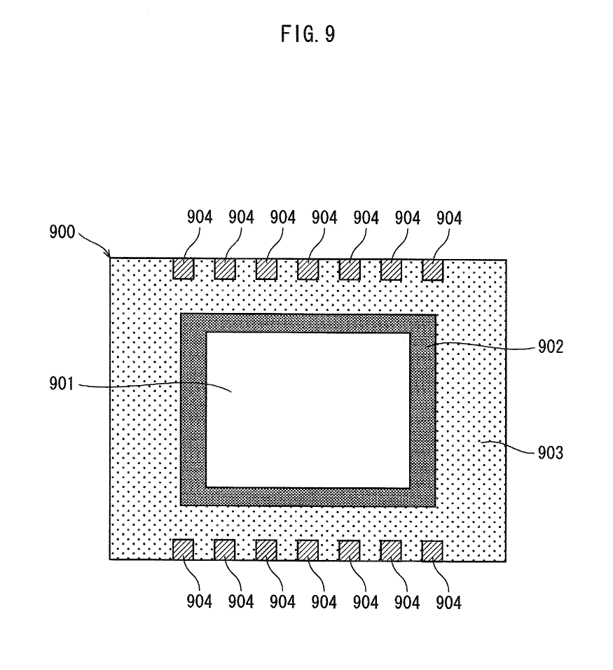

### DESCRIPTION OF EMBODIMENTS

The following describes Embodiments 1 and 2 of a solid-state imaging device according to the present invention with reference to the drawings.

First, the structure of the solid-state imaging device according to the Embodiments is described, after which the features of each Embodiment are described.

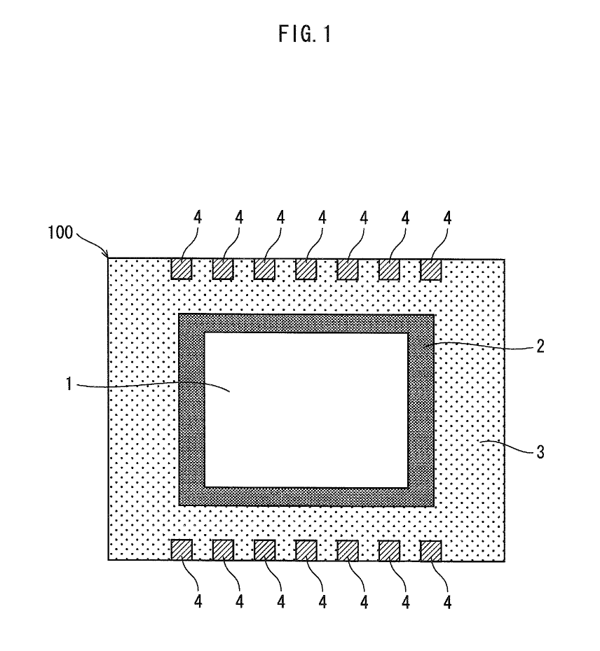

FIG. 1 is a plan view showing the structure of the solid-state imaging device according to the Embodiments.

As shown in FIG. 1, a solid-state imaging device 100 described in the Embodiments is provided with an imaging area 1, an optical black area (hereinafter, “OB area”) 2, and a peripheral area 3 on a semiconductor substrate, similar to the above conventional solid-state imaging device 900.

In the imaging area 1 and the OB area 2, photoreceptors (pixels) formed by photodiodes or the like are arranged in a two-dimensional matrix to form a pixel array. Each pixel in the imaging area 1 and the OB area 2 is formed at the same time through the same basic process and has the same structure.

The photoreceptor in the OB area 2 is used as a dummy pixel having the same structure as the pixels in the imaging area 1 in order to adjust the brightness level of processing image signals read by the photoreceptors in the imaging area 1. Output signals from the dummy pixels are used as black reference signals.

Therefore, while omitted from FIG. 1, a light-blocking film made of a metal such as aluminum is formed in the OB area 2, unlike in imaging area 1. The photoreceptors throughout the OB area 2 are covered by the metal light-blocking film.

The peripheral area 3 includes peripheral circuitry such as a receiving circuit for receiving the image signal of each photoreceptor in the imaging area 1 and the OB area 2, a drive circuit for driving the pixel array, a variety of signal processing circuits, and the like which are formed by the same process as the imaging area 1 and the OB area 2 (such as a CMOS process). The peripheral area 3 also includes a plurality of bonding pads 4 used for connection to an external device, a plurality of metal wiring lines connecting the peripheral circuitry and the photoreceptors with the bonding pads 4, and the like.

While omitted from FIG. 1, a color filter is provided in the upper layer of the solid-state imaging device 100 as a light-separating means. Furthermore, a microlens is provided on the color filter as a way to focus light that enters the photoreceptors more efficiently.

Note that in the example shown in FIG. 1, the OB area 2 is provided on all four sides of the imaging area 1, but as long as the OB area 2 can measure a balanced black reference, a variety of arrangements are possible. For example, the OB area 2 may be provided on two opposite sides of the valid pixel region, or in one or more blocks along portions of the sides or in the corners.

While the position of the OB area 2 is not particularly limited, the OB area 2 is particularly effective when positioned in a location at which light entering the OB area 2 might be reflected between the light-blocking film, the color filter, and the microlens and enter the imaging area 1 as stray light.

### Embodiment 1

### 1. Structure

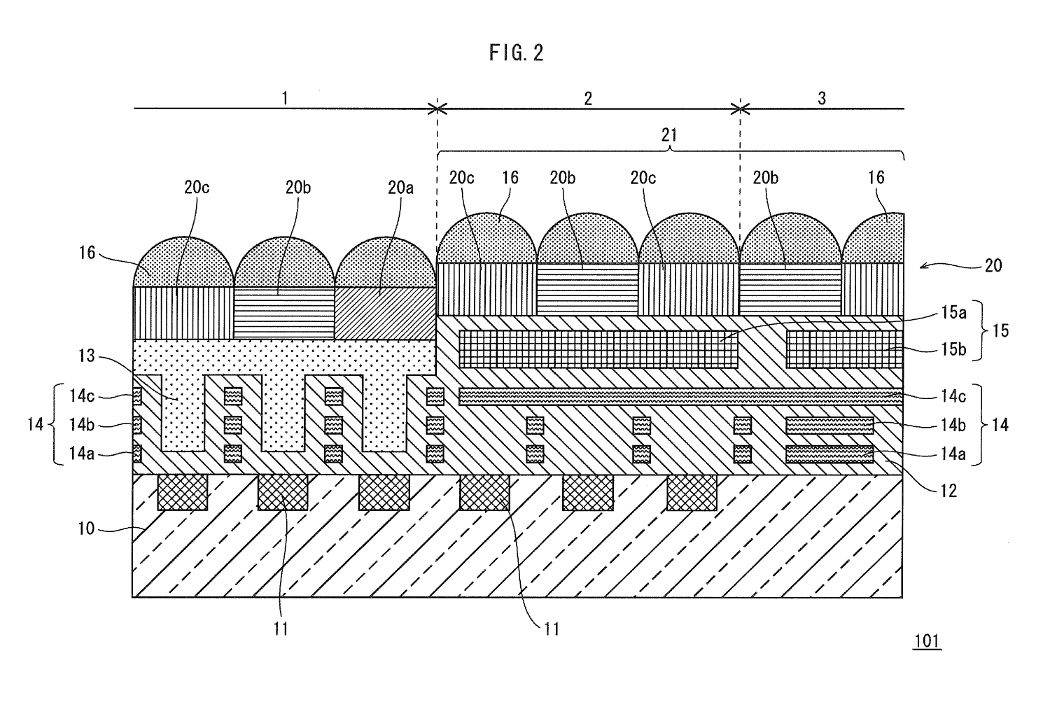

FIG. 2 is a cross-section diagram of showing the structure of the solid-state imaging device according to Embodiment 1.

Note that the solid-state imaging device according to Embodiment 1 has the above-described plan view structure.

As shown in FIG. 2, the solid-state imaging device 101 is a specific example of the present invention in which CMOS image sensors are formed on a monocrystalline silicon substrate. FIG. 2 shows an area from the edge of the imaging area 1 to the peripheral area 3.

In FIG. 2, photodiodes 11 are formed on the silicon substrate 10 as photoreceptors. Light that enters through the receiving surface of the photodiodes 11 in the silicon substrate 10 undergoes photoelectric conversion, and a signal charge is accumulated.

Note that in addition to the photodiodes 11, a variety of MOS transistors (pixel transistors) and the like that form pixel circuits are provided in the silicon substrate 10. As such components are not directly related to the features of the present invention, they are omitted from the drawings.

An interlayer insulator 12 is provided on the silicon substrate 10 with a gate oxide and the like, not shown in the figures, therebetween. A plurality of wiring layers 14, 15 are provided in the interlayer insulator 12 to yield wiring patterns 14a, 14b, 14c, 15a, and 15b.

In this example, the wiring layer 14 in the imaging area 1 is a three-layer laminate, whereas the wiring layers 14 and 15 in areas other than the imaging area 1 (i.e. the OB area 2 and the peripheral area 3) are a four-layer laminate.

A transparent silicon oxide film or the like is used as the material for the interlayer insulator 12. As examples of the material for the wiring layers 14 and 15, a film having copper as the main component is used as the lower wiring layer 14 near the silicon substrate 10, whereas a film having aluminum, which has strong light-shielding properties, as the main component is used for the uppermost wiring layer 15.

In Embodiment 1, a light-blocking film 15a is formed from the uppermost aluminum wiring layer 15. In other words, the aluminum writing layer (15a) in the OB area 2 functions as the light-blocking film. This light-blocking film is also indicated by the reference sign “15a”.

The light-blocking film 15a is provided in an area corresponding to the above-described OB area 2 to block light entering from above and prevent the light from entering into the photoreceptors in the OB area 2. In the imaging area 1, on the other hand, light entering from above passes through a waveguide 13, passing between the wiring patterns 14a, 14b, and 14c (between adjacent wiring patterns in plan view) to enter the photodiodes 11.

The interlayer insulator 12 is further layered above the wiring layer 15 (light-blocking film 15a). The interlayer insulator 12 functions as a planarizing film and as a protective film. On the waveguide 13 in the imaging area 1 and the uppermost surface of the interlayer insulator 12 in the OB area 2 and the peripheral area 3, a color filter area 20 including color filters 20a, 20b, and 20c is formed. A microlens 16 (for example, an on-chip lens) is formed on the color filter area 20.

The color filter area 20 and the microlens 16 are formed to cover the entire imaging area 1 and OB area 2, as well as the peripheral area 3 excluding the bonding pads 4.

The color filter area 20 is formed at the same time in the imaging area 1, the OB area 2, and the peripheral area 3 during the formation process of the color filters corresponding to the pixels. In other words, the color filters are formed in all of the areas at the same time, using the same materials and applying the filters to the same thickness.

The color filter area 20 functions as a regular color filter in the imaging area 1. In this embodiment, red, green, and blue (RGB) primary color filters are arranged in a predetermined pattern (such as a Bayer arrangement) so that RGB light components enter the photodiode 11 of the pixels allocated to the colors red, green, and blue respectively.

The color filter 20a is for the color green, the color filter 20b is for the color blue, and the color filter 20c is for the color red. The color filter for the color red, for example, is referred to as a red filter.

Note that while FIG. 2 shows the color filters 20a, 20b, and 20c in the imaging area 1 once each for the sake of illustration, the color filters 20a, 20b, and 20c in the imaging area 1 are actually in a Bayer arrangement.

By contrast, in the OB area 2 and the peripheral area 3, a different color filter pattern than in the imaging area 1 is used above the light-blocking film 15a, namely a pattern (structure) to particularly reduce light components of visible light having a long wavelength and a short wavelength. In other words, the color filter area 20 in the OB area 2 is also a light-absorption unit 21. The principle behind the light-absorption unit 21 is described below.

Specifically, when a three primary color filter is used in the imaging area 1, the light-absorption unit 21 is formed by a checkered pattern composed of blue filters 20b, which have the lowest degree of transparency for long wavelengths of light, and red filters 20c, which have the lowest degree of transparency for short wavelengths of light.

In other words, the blue filter 20b and the red filter 20c are respectively the first filter and second filter of the present invention.

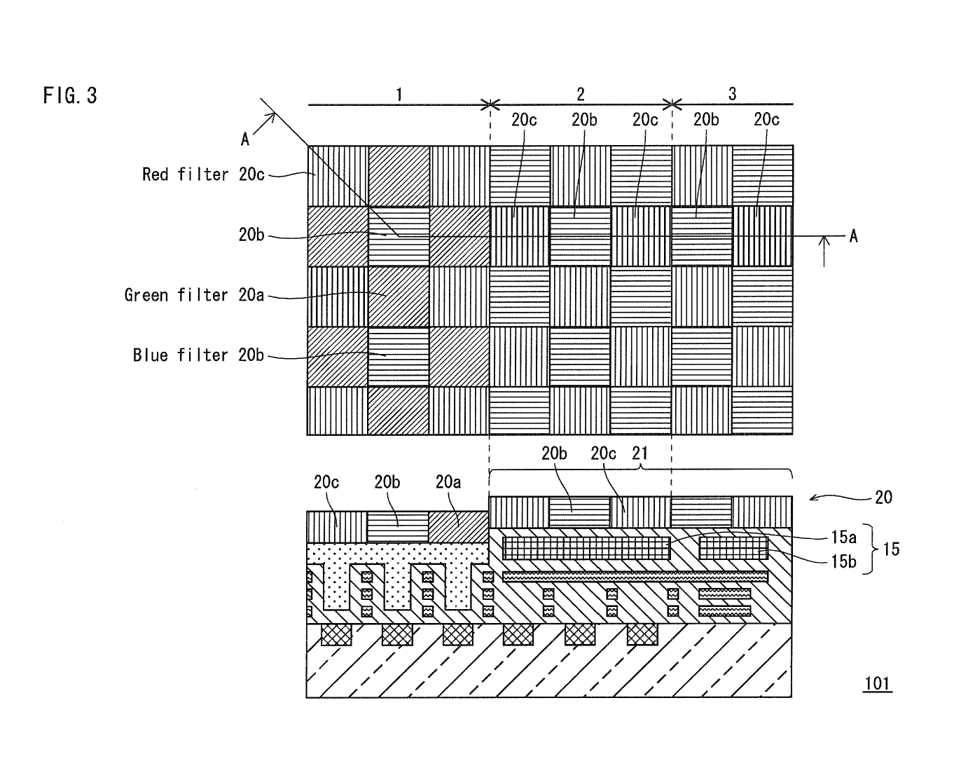

FIG. 3 is a plan view showing the solid-state imaging device according to Embodiment 1 without the microlens 16. In the OB area 2 and the peripheral area 3, the checkered pattern of the light-absorption unit 21 is illustrated.

Note that below the plan view in FIG. 3, a cross-section diagram of a cross section from A to A viewed in the direction of the arrows is shown. The positions of the color filters 20a, 20b, and 20c correspond between the plan view and the cross-section diagram.

As shown in FIG. 3, the Bayer arrangement is used for the three primary color filters 20a, 20b, and 20c in the imaging area 1, whereas starting at the OB area 2 (i.e. in the OB area 2 and the peripheral area 3), the color filters are arranged in a checked pattern of blue filters 20b and red filters 20c.

This “checkered pattern” refers a pattern in which two shapes alternate. The two shapes may, for example, be quadrilaterals, such as squares or rectangles; polygons, such as hexagons; circles or ellipses; etc.

Furthermore, as long as the two shapes alternate, they may be arranged alternately in a lattice shape as described above, or in a staggered arrangement.

Examples of arrangements other than a checkered pattern are described below.

The color filters are formed by lithography to yield an appropriate plane pattern. For example, the green filter 20a is made from material that allows light with a wavelength in a range of approximately 500 nm to 600 nm to pass through and material that is photosensitive to ultraviolet light. The blue filter 20b is made from material that allows light with a wavelength in a range of approximately 400 nm to 500 nm to pass through and material that is photosensitive to ultraviolet light. The red filter 20c is made from material that allows light with a wavelength in a range of approximately 600 nm to 700 nm to pass through and material that is photosensitive to ultraviolet light.

Note that forming the red filter 20c so as only to include only non-metallic material with respect to the red organic pigment achieves the advantageous effect of simplifying the etching process.

### 2. Principle Behind Absorption

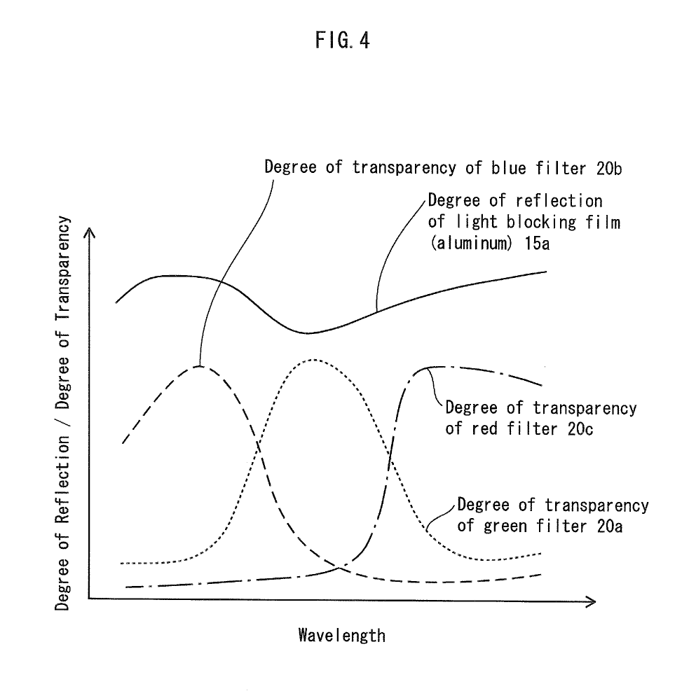

FIG. 4 is a conceptual diagram of separation characteristics of the three primary color filters and the degree of reflection of the light-blocking film (aluminum). Note that FIG. 4 shows the relationship between wavelength and degree of transparency for each filter, as well as the relationship between wavelength and degree of reflection for the light-blocking film.

As shown in FIG. 4, the blue filter 20b (indicated by a dashed line) has a high degree of transparency for short wavelengths of light (i.e. blue light) and a low degree of transparency for long wavelengths of light (such as green or red light). In other words, the blue filter 20b allows short wavelengths of light to pass through, while absorbing long wavelengths of light.

On the other hand, the red filter 20c (indicated by an alternating long and short dashed line) has a low degree of transparency for short wavelengths of light (such as blue light) and a high degree of transparency for long wavelengths of light (i.e. red light). In other words, the red filter 20c absorbs short wavelengths of light, while allowing long wavelengths of light to pass through.

As shown in FIG. 4, the light-blocking film 15a (indicated by a straight line) has strong light-shielding properties, reflecting light of all wavelengths.

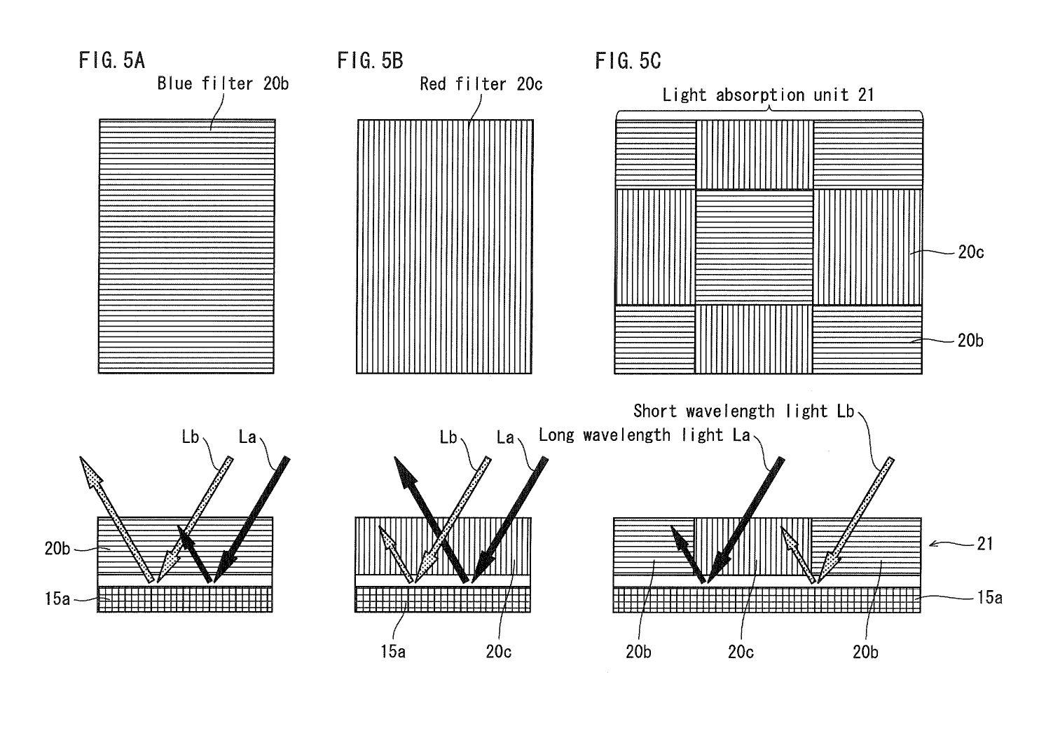

FIGS. 5A, 5B, and 5C are conceptual diagrams of reflection characteristics of the color filters 20b and 20c provided in the OB area 2. Note that in FIG. 5A, the blue filter 20b is provided above the light-blocking film 15a; in FIG. 5B, the red filter 20c is provided above the light-blocking film 15a; and in FIG. 5C, the light-absorption unit 21 is provided above the light-blocking film 15a.

First, the blue filter 20b shown in FIG. 5A is described.

When light of a short wavelength (blue light) Lb enters, the short wavelength light Lb passes through (penetrates) the blue filter 20b as is, as shown in FIG. 4, being reflected upon reaching the surface of the light-blocking film 15a. After being reflected on the surface of the light-blocking film 15a, the short wavelength light Lb exits the blue filter 20b as is without being absorbed by the blue filter 20b.

On the other hand, when light of a long wavelength (red light) La enters, the long wavelength light La is partially absorbed by the blue filter 20b, as shown in FIG. 4. The remaining portion of the long wavelength light La that is not absorbed is reflected upon reaching the surface of the light-blocking film 15a. After being reflected on the surface of the light-blocking film 15a, the long wavelength light La is absorbed by the blue filter 20b.

Next, the red filter 20c shown in FIG. 5B is described.

When light of a long wavelength (red light) La enters, the long wavelength light La passes through (penetrates) the red filter 20c as is, as shown in FIG. 4, being reflected upon reaching the surface of the light-blocking film 15a. After being reflected on the surface of the light-blocking film 15a, the long wavelength light La exits the red filter 20c as is without being absorbed by the red filter 20c.

On the other hand, when light of a short wavelength (blue light) Lb enters, the short wavelength light Lb is partially absorbed by the red filter 20c, as shown in FIG. 4. The remaining portion of the short wavelength light Lb that is not absorbed is reflected upon reaching the surface of the light-blocking film 15a. After being reflected on the surface of the light-blocking film 15a, the short wavelength light Lb is absorbed by the red filter 20c.

As opposed to these two examples of the color filters 20b and 20c respectively, the light-absorption unit 21 includes both the blue filter 20b and the red filter 20c in a checkered pattern, as shown in FIG. 5C. As a result, the light-absorption unit 21 has a structure in which filters having mutually different light-separation characteristics alternate.

As shown in FIG. 5C, when light of a short wavelength (blue light) Lb enters the blue filter 20b, the short wavelength light Lb penetrates the blue filter 20b as is without being absorbed and is reflected upon reaching the surface of the light-blocking film 15a. After being reflected, the short wavelength light Lb enters the red filter 20c adjacent to the blue filter 20b. After entering the red filter 20c, the short wavelength light Lb is absorbed by the red filter 20c.

On the other hand, when light of a long wavelength (red light) La enters the red filter 20c, the long wavelength light La penetrates the red filter 20c as is without being absorbed and is reflected upon reaching the surface of the light-blocking film 15a. After being reflected, the long wavelength light La enters the blue filter 20b adjacent to the red filter 20c. After entering the blue filter 20b, the long wavelength light La is absorbed by the blue filter 20b.

In other words, the long wavelength light La, which easily enters through the red filter 20c, is reduced by the light-blocking film 15a and the blue filter 20b. At the same time, the short wavelength light Lb, which is easily reflected, is reduced by the light-blocking film 15a and the red filter 20c. This structure thus moderates a reduction in image quality due to stray light in the imaging area.

As a result, the structure of Embodiment 1, in particular the structure of the light-absorption unit 21 that includes the blue filter 20b and the red filter 20c, filters that have mutually different light-separation characteristics, reduces the amount of light passing through the OB area 2 and the amount of light reflected from the OB area 2 due to the combined effect of the light-blocking film 15a and the color filters 20b and 20c in the light-absorption unit 21. Therefore, short wavelength light and long wavelength light entering into and reflected in the OB area 2 are efficiently reduced (absorbed), thus improving light-shielding properties, reducing stray light entering the imaging area 1, and moderating a reduction in image quality.

### 3. Method of Manufacturing

The solid-state imaging device 101 can be manufactured using technology for manufacturing a conventional solid-state imaging device. In other words, the solid-state imaging device 101 can be manufactured by forming the color filter area 20 so that the color filters in the OB area 2 and the peripheral area 3 are formed in a checkered pattern including the blue filters 20b and the red filters 20c, in the same way that the color filters 20a, 20b, and 20c are formed in a predetermined pattern (such as a Bayer arrangement) in the imaging area 1.

This method of manufacturing simply changes the pattern of the color filters 20a, 20b, and 20c in the OB area 2 and the peripheral area 3. Therefore, the solid-state imaging device 101 according to Embodiment 1 is achieved without greatly changing the conventional manufacturing process. Furthermore, forming the light absorption unit from the same material as the color filters in the imaging area 1 reduces the number of manufacturing processes and the cost of material, thus resulting in a low-cost manufacturing process.

Furthermore, since the blue filter 20b and the red filter 20c are in a planar formation (i.e. not a layered formation) in the light-absorption unit 21 and are arranged to alternate on the same foundation as in other areas (the “foundation” referring, for example to the upper surface of the waveguide 13 in the imaging area 1 or of the uppermost portion of the interlayer insulator 12 in the OB area 2 and the peripheral area 3), the upper surface of the imaging area 1, the OB area 2, and the peripheral area 3 is nearly planarized after formation of the color filters.

In other words, no difference in level occurs in the imaging area 1, the OB area 2, and the peripheral area 3 due to a difference in thickness of the color filter. Therefore, during the subsequent microlens formation process, unevenness is prevented in photoreceptive resin applied to form the microlens 16, thereby improving manufacturing yield and image quality.

Furthermore, since the upper surface of the imaging area 1, the OB area 2, and the peripheral area 3 are nearly planarized, no special process to planarize the OB area 2 and the peripheral area 3 after formation of the color filters is necessary, thereby achieving a method of manufacturing the solid-state imaging device 101 at a low cost.

### Embodiment 2

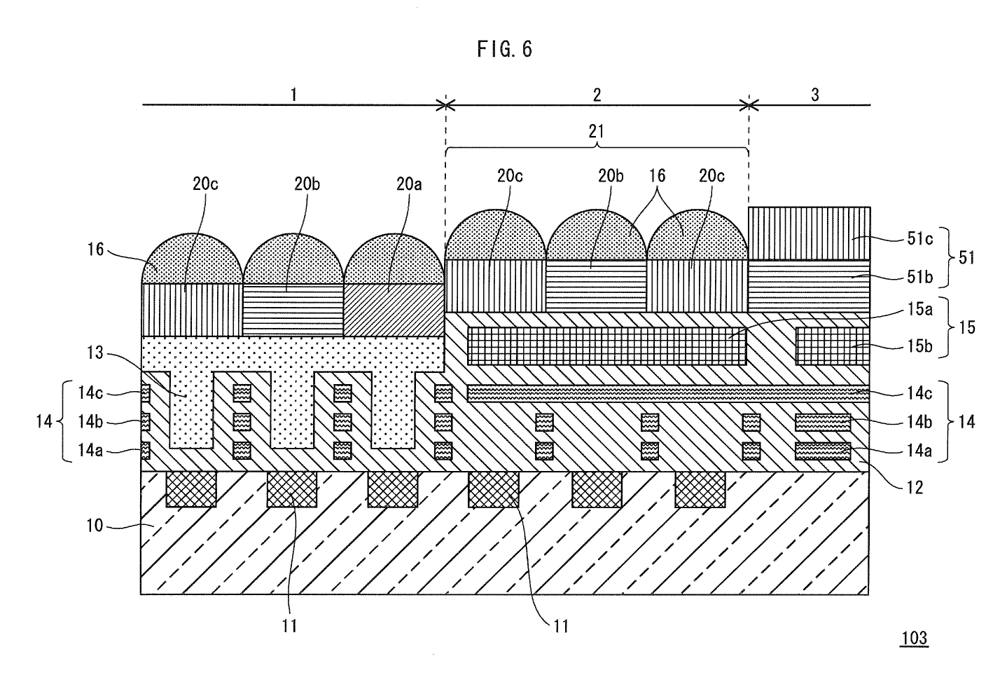

FIG. 6 is a cross-section diagram showing a solid-state imaging device 103 according to Embodiment 2 having the above-described plan view structure.

As shown in FIG. 6, Embodiment 2 is a specific example of the present invention in which CMOS image sensors are formed on a monocrystalline silicon substrate, as in Embodiment 1. FIG. 6 shows an area from the edge of the imaging area 1 to the peripheral area 3.

In the color filter area in the imaging area 1, three primary color filters 20a, 20b, and 20c, corresponding to red, green, and blue, are arranged in a predetermined pattern as in Embodiment 1. In the color filter area in the OB area 2, a light-absorption unit 21 is provided as in Embodiment 1, the light-absorption unit 21 having color filters in a checkered pattern that differs from the pattern in the imaging area 1.

On the other hand, in the peripheral area 3, unlike in Embodiment 1, a light-absorption layer 51 is provided, the light-absorption layer 51 having a blue filter 51b and a red filter 51c layered therein. In this Embodiment, the blue filter 51b is the lower layer in the light-absorption layer 51 (i.e. the blue filter 51b is positioned closer to the wiring layer 15b).

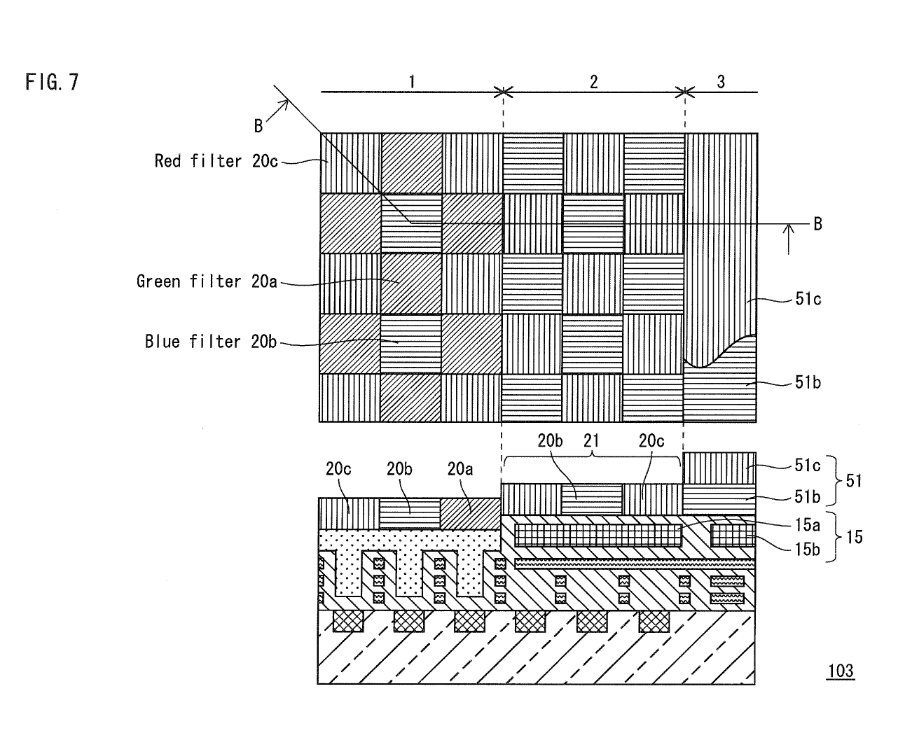

FIG. 7 is a plan view showing the solid-state imaging device 103 according to Embodiment 2 without the microlens 16. In the OB area 2, the checkered pattern of the light-absorption unit 21 is illustrated, whereas in the peripheral area 3, the color filters 51c and 51b of the light-absorption layer 51 are illustrated.

Note that below the plan view in FIG. 7, as in FIG. 3, a cross-section diagram of a cross section from B to B viewed in the direction of the arrows is shown. The positions of the color filters 20a, 20b, and 20c, 51b, and 51c correspond between the plan view and the cross-section diagram.

In the peripheral area 3, as shown in FIGS. 6 and 7, the light-absorption layer 51 is formed above the wiring layer (light-blocking film) 15b with the blue filter 51b and the red filter 51c forming a layered pattern (layered structure) therein. Note that the light-absorption layer 51 in the solid-state imaging device 103 according to Embodiment 2 can be manufactured by forming the blue filter 51b in the lower layer in conjunction with formation of the blue filter 20b in the imaging area 1 and the OB area 2 and by subsequently forming the red filter 51c in the upper layer in conjunction with formation of the red filter 20c in the imaging area 1 and the OB area 2.

As shown in FIG. 6, the blue filter 20b and the red filter 20c are arranged in a checkered pattern in the light-absorption unit 21. Therefore, as in Embodiment 1, the light-absorption unit 21 has a structure in which filters having mutually different light-separation characteristics alternate.

As a result, long wavelength light, which easily enters through the red filter 20c, is reduced by the light-blocking film 15a and the blue filter 20b. At the same time, short wavelength light, which is easily reflected, is reduced by the light-blocking film 15a and the red filter 20c. Therefore, both incident light and reflected light of short and long wavelengths is effectively reduced in the OB area 2.

Layering the blue filter 20b and the red filter 20c in the light-absorption layer 51 yields a filter structure in which short and long wavelengths of light are simultaneously reduced (absorbed). Since short and long wavelengths of light are simultaneously absorbed in the peripheral area 3, where the light-blocking film 15a is not formed, stray light occurring at the wiring layer 15 is reduced (i.e. light that reflects off the wiring layer 15b, light that passes between wires or is reflected off wires and enters a lower level area, etc.).

Since the blue filter 20b and the red filter 20c are in a layered arrangement in the light-absorption layer 51, short and long wavelengths of light are simultaneously absorbed, thus providing the light-absorption layer 51 with strong light-shielding properties.

Therefore, with the structure of Embodiment 2, both light passing through to the OB area 2 and light reflected off the OB area 2 is reduced by the combined effect of the light-blocking film 15a and the light-absorption unit 21, and furthermore, stray light produced by the wiring layer 15b or the like in the peripheral area 3, which lacks the light-blocking film 15a, is reduced by the light-absorption layer 51. Therefore, stray light entering the imaging area 1 is reduced, thus moderating a reduction in image quality. Note that the light-blocking film 15a may be formed in the peripheral area 3.

In the OB area 2 and the peripheral area 3, the light-absorption unit 21 is first provided, and then the light-absorption layer 51 is provided. The imaging area 1 and the OB area 2 are thus formed to approximately the same height, whereas the peripheral area 3 is formed to be higher than the OB area 2. A step is thus formed where the OB area 2 and the peripheral area 3 meet, thus reducing a difference in level caused by an abrupt change in film thickness of the color filters 20b, 20c, 51b, and 51c.

Accordingly, during the subsequent microlens formation process, the difference in height between the surface of the color filters 20a, 20b, and 20c in the imaging area 1 and the surface of the color filters in the OB area 2 is slight, thus preventing unevenness in the photoreceptive resin applied to form the microlens 16. The microlens 16 in the imaging area 1 is thus formed evenly, thereby improving manufacturing yield and image quality. At this point, a difference in level between the color filters 20b, 20c, and 51c of the OB area 2 and the peripheral area 3 does occur, yet this unevenness is at a distance from the imaging area 1 and thus has little effect.

As for the method of manufacturing, the solid-state imaging device 103 according to Embodiment 2 is achieved by simply changing the pattern of the color filters 20a, 20b, and 20c, 51b, and 51c, without greatly changing the conventional manufacturing process. Accordingly, the number of manufacturing processes and the cost of material are reduced. As a result, Embodiment 2 has the advantage of being manufactured at low-cost.

Note that in Embodiment 2, it is preferable that the light-absorption unit 21 have a width of at least 50 μm. A width of this range reduces unevenness in subsequent application due to a difference in film thickness with the light-absorption layer 51. In other words, even if there is a difference in film thickness with the light-absorption layer 51, if the light-absorption unit 21 extends away from the imaging area 1 at least 50 μm, unevenness upon application is reduced.

In Embodiment 2, the light-absorption unit 21 is formed above the OB area 2, and the light-absorption layer 51 above the peripheral area 3, but the arrangement of the absorption unit and layer is not limited to these respective areas. As long as the light-absorption unit 21 has a width of at least 50 μm, the light-absorption layer 51 may overlap the OB area 2.

Furthermore, in Embodiment 2, the red filter 20c is formed above the blue filter 20b in the light-absorption layer 51, but the order of layering is not limited in this way. A layered pattern in which the blue filter 51c is formed as the lower layer, after which the red filter 51b is formed as the upper surface, is also possible.

### Modifications

### 1. Color Filter

### (1) Type

In the above Embodiments, primary color filters are used, but complimentary color filters may be used instead. In this case, it is preferable to form the checkered pattern with cyan filters and magenta filters.

### (2) Patterns

In the above Embodiments, blue filters 20b and red filters 20c having the same square shape and size are arranged like checkerboard squares (i.e. as a regular matrix) in plan view to yield the checkered pattern in the light-absorption unit 21 formed in the OB area 2. In other words, the blue filters 20b and the red filters 20c are arranged so that adjacent longitudinal and lateral sides thereof lie along straight lines.

However, in the light-absorption unit 21, it suffices for adjacent first layers and second layers to alternate above the light-blocking film 15a, so that light passing through the first layer is reflected on the light-blocking film 15a and then absorbed by the second layer. The first layer and the second layer do not have to be in a checkerboard pattern. Note that it is preferable for the direction in which the adjacent first layers and second layers alternate to at least extend away from the imaging area 1.

The first layer and the second layer are not limited to color filters, but considering the manufacturing process, manufacturing costs, etc., it is preferable to use the same filters as the color filters 20a, 20b, and 20c formed in the imaging area 1. Below, a light-absorption unit that uses red and blue filters and that differs from the Embodiments is described.

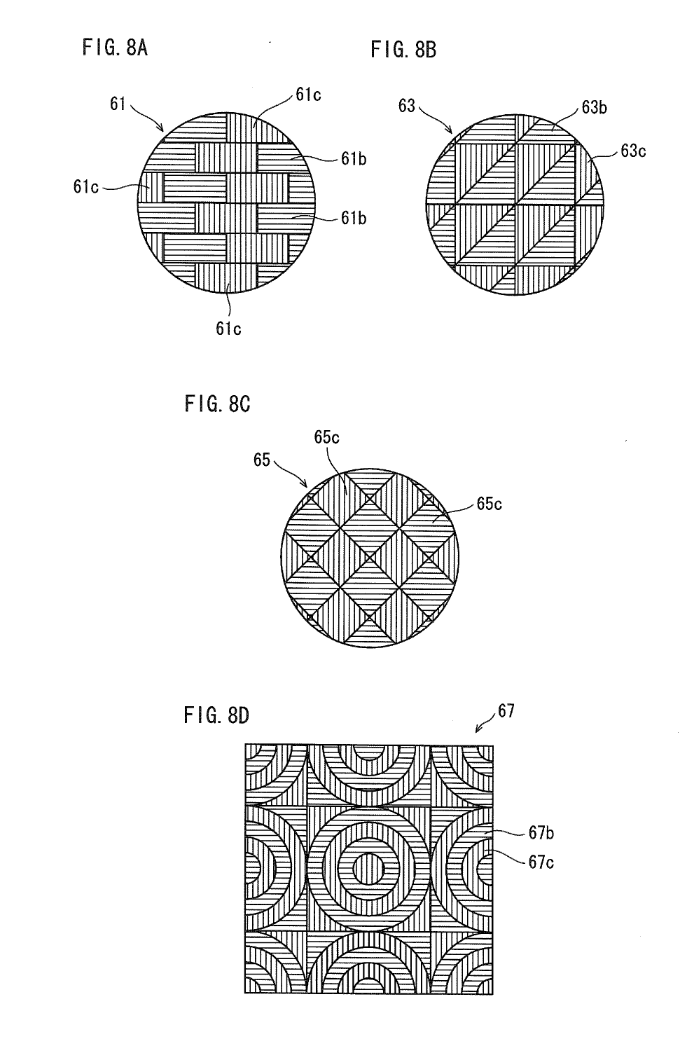

FIGS. 8A, 8B, 8C, and 8D are plan views showing light-absorption layers according to the present Modification.

As shown in FIG. 8A, in a light-absorption layer 61, blue and red filters 61b and 61c may be quadrilaterals, such as rectangles, arranged to alternate longitudinally and laterally.

As shown in FIG. 8B, in a light-absorption layer 63, blue and red filters 63b and 63c may be triangles, such as right isosceles triangles, arranged to alternate longitudinally and laterally.

As shown in FIG. 8C, in a light-absorption layer 65, blue and red filters 65b and 65c may be arranged to be adjacent in directions other than the longitudinal and lateral directions. For example, the blue and red filters 65b and 65c may be quadrilaterals (squares) arranged to alternate diagonally.

As shown in FIG. 8D, in a light-absorption layer 67, blue and red filters 67b and 67c may be ring shaped. For example, concentric circular ring-shaped blue and red filters 67b and 67c may alternately increase in size.

### (3) First and Second Filter

In the above Embodiments, the blue filters 20b and 51b and the red filters 20c and 51c are used as the first filter and the second filter, but other combinations of filters may be used. For example, a combination of red filters and green filters may be used, as may a combination of blue filters and green filters.

Note that a combination of blue filters and red filters achieves the advantageous effect of efficiently absorbing both long wavelengths of light, which enter easily, and short wavelengths of light, which are reflected easily.

### 2. Light-Blocking Film

In the above Embodiments, the light-blocking film 15a functions as a wiring layer, but instead of a wiring layer, a film (such as a metal film) formed only for blocking light may be adopted. The light-blocking film may further be formed in the peripheral area 3.

### 3. Microlens

In the above Embodiments, the microlens 16 is formed in the entire OB area 2, but the microlens 16 need not be formed in the entire OB area 2 and may, for example, be formed only in a portion of the OB area 2 near the imaging area 1. Note that forming the microlens near the imaging area 1 improves the quality of the microlens formed in the imaging area 1.

### 4. Solid-State Imaging Device

In the above Embodiments, an example of the present invention applied to an MOS solid-state imaging device is described, but the present invention may similarly be applied to a CCD solid-state imaging device.

Furthermore, in the Embodiments, a CMOS image sensor with a waveguide structure is used, but the present invention is not limited to this structure. For example, the present invention may be used in a structure in which light passes through a transparent oxide film between wires, without the use of waveguides, or in a structure that uses a photoelectric conversion film without using photodiodes. The present invention may also be used in a back illuminated image sensor or a monochrome image sensor.

### 5. Imaging Area

In the above Embodiments, while not shown in the figures, a transparent planarizing film may be used between either the waveguide 13 and the color filters 20, or between the color filters 20 and the microlens 16.

In the above Embodiments, transparent silicon oxide film is used as the material for the insulator 12 above the uppermost metal wiring. A silicon nitride film or the like may be used as a protective film additionally layered thereabove.

### 6. Other

In the Embodiments and the Modifications, respective characteristics were described separately, but the structures in the Embodiments and Modifications may be combined with one another.

### INDUSTRIAL APPLICABILITY

With the present invention, an inexpensive solid-state imaging device with high image quality is achieved. Therefore, the present invention is particularly useful as a solid-state imaging device provided with color filters and as a method of manufacturing of the same. The present invention is not limited to digital still cameras or digital video cameras, but rather is widely applicable to monitoring cameras, medical endoscopes, etc.

### REFERENCE SIGNS LIST

1 imaging area

2 OB (optical black) area

3 peripheral area

10 silicon substrate

11 photodiode

15a light-blocking film

16 microlens

20 color filter area

21 light-absorption unit

101 solid-state imaging device

1. A solid-state imaging device comprising:
a substrate having an imaging area and an optical black area provided at a periphery of the imaging area, a plurality of first photoreceptors being arranged on the substrate in a two-dimensional pattern in the imaging area, and a plurality of second photoreceptors being arranged on the substrate and covered by a light-blocking film located in the optical black area; and
a light-absorption unit provided above the optical black area, wherein
the light-absorption unit includes a first filter and a second filter in an alternating arrangement, the first filter allowing visible light of a first type to pass through, and the second filter absorbing visible light of the first type that passes through the first filter and is reflected off the light-blocking film.

2. The solid-state imaging device of claim 1, wherein
the second filter allows visible light of a second type to pass through, and
the first filter absorbs visible light of the second type that passes through the second filter and is reflected off the light-blocking film.

3. The solid-state imaging device of claim 2, further comprising:
a peripheral area provided at a periphery of the optical black area, the peripheral area including peripheral circuitry and a bonding pad, wherein
the light-absorption unit is further provided above the peripheral area.

4. The solid-state imaging device of claim 2, further comprising:
a peripheral area provided at a periphery of the optical black area, the peripheral area including peripheral circuitry and a bonding pad; and
a light-absorption layer provided above the peripheral area and including at least two types of filters having mutually different light-separation characteristics and provided layered on each other.

5. The solid-state imaging device of claim 4, wherein
the light-absorption layer includes at least the first filter and the second filter.

6. The solid-state imaging device of claim 1, further comprising:
a plurality of different types of color filters provided in the imaging area in correspondence with the first photoreceptors, wherein
the first filter and the second filter are each of the same material as a respective one of the different types of color filters.

7. The solid-state imaging device of claim 1, wherein
at least one of the first filter and the second filter is formed only from organic pigment and non-metallic material.

8. The solid-state imaging device of claim 1, further comprising:
a light-absorption layer provided above the optical black area and including at least two types of filters having mutually different light-separation characteristics and provided layered on each other, wherein
the light-absorption unit is provided closer to the imaging area than the light-absorption layer is.

9. A method of manufacturing a solid-state imaging device with a substrate having an imaging area and an optical black area provided at a periphery of the imaging area, a plurality of first photoreceptors being arranged on the substrate in a two-dimensional pattern in the imaging area, and a plurality of second photoreceptors being arranged on the substrate and covered by a light-blocking film located in the optical black area, the method comprising:
a formation step of forming a first filter and a second filter in an alternating arrangement above the optical black area, the first filter allowing visible light of a first type to pass through, and the second filter absorbing visible light of the first type that passes through the first filter and is reflected off the light-blocking film.

10. The method of manufacturing a solid-state imaging device of claim 9, wherein
the first filter and the second filter are formed in a checkered pattern.

11. The method of manufacturing a solid-state imaging device of claim 9, wherein
the solid-state imaging device further includes a peripheral area provided at a periphery of the optical black area, the peripheral area including peripheral circuitry and a bonding pad, and
during the formation step, the first filter and the second filter are also formed in the alternating arrangement in the peripheral area.

12. The method of manufacturing a solid-state imaging device of claim 9, wherein
the solid-state imaging device further includes a peripheral area provided at a periphery of the optical black area, the peripheral area including peripheral circuitry and a bonding pad, and
the method further comprises, after the step of forming the first filters and the second filters, the step of layering, in the peripheral area, at least two types of filters having mutually different light-separation characteristics.

13. The method of manufacturing a solid-state imaging device of claim 9, wherein
the first filter and the second filter are formed from the same material as a plurality of color filters provided in the imaging area in correspondence with the first photoreceptors.

14. The method of manufacturing a solid-state imaging device of claim 9, wherein
the formation step of forming the first filter and the second filter includes forming a plurality of color filters in the imaging area in correspondence with the first photoreceptors.
